(19) United States
(12) Patent Application Publication
(10) Pub. No.: US 2014/0045287 A1
(43) Pub. Date: Feb. 13, 2014

(54) METHOD FOR MANUFACTURING DISPLAY DEVICE, METHOD FOR MANUFACTURING LIQUID CRYSTAL DISPLAY DEVICE, AND LIQUID CRYSTAL DISPLAY DEVICE

(71) Applicants: Takatoshi Kira, Osaka (JP); Hiroki Makino, Osaka (JP)

(72) Inventors: Takatoshi Kira, Osaka (JP); Hiroki Makino, Osaka (JP)

(73) Assignee: SHARP KABUSHIKI KAISHA, Osaka (JP)

(21) Appl. No.: 14/112,212

(22) PCT Filed: Apr. 13, 2012
(86) PCT No.: PCT/JP2012/060109

§ 371 Date: Oct. 16, 2013

(30) Foreign Application Priority Data
Apr. 20, 2011 (JP) 2011-094037

(51) Int. Cl. H01L 33/02

(52) U.S. Cl. CPC H01L 33/02
USPC 438/30; 438/33

(57) ABSTRACT

A method of manufacturing liquid crystal display devices according to the present invention includes: forming a protective film on a first base substrate; forming a circuit element part on the first base substrate and/or the protective film; bonding a second base substrate to the first base substrate to form bonded substrates including both substrates, the circuit element part being therebetween; forming a first incision on a outer surface of the first base substrate on which the protective film is formed, at a location overlapping with the protective film; wet-etching the formed first incision to make the incision deeper; forming a second incision on an outer surface of the second base substrate at a location overlapping the first incision, and dividing the bonded substrates along the first incision and the second incision, thereby forming a plurality of individual bonded substrates.

### TECHNICAL FIELD

The present invention relates to a method of manufacturing a display device, a method of manufacturing a liquid crystal display device, and a liquid crystal display device.

### BACKGROUND ART

A display device with a display panel such as a liquid crystal panel is used in electronics such as mobile phones, smartphones, information terminal devices such as PDAs, computers, and television receivers. Such a display device is manufactured by forming element parts provided with terminal parts on one of a pair of substrates made of glass or the like, bonding the substrates together, and then forming an incision such as a scribe line from the outside of the bonded substrates in order to cut the bonded substrates into a plurality of individual substrates along the incision.

In such a method to cut the bonded substrates, an incision such as a scribe line using a scribe scheme is formed on the outside of the bonded substrates. Thus, cracks or the like originating from this incision may appear on the surface of the bonded substrates. A method is known in which, after the incision is formed from the outside of the bonded substrates, the bonded substrates as wet-etched to make the depth of the incision deeper, thereby making it easier to cut the bonded substrates along the incision.

However, when wet-etching is performed after the incision is formed on the bonded substrates, the incision sometimes becomes deep enough to go through the substrate, with the etching solution then entering between the pair of substrates through the incision. This caused the element parts formed between the pair of substrates to be corroded.

Disclosed in Patent Document 1 is a method to prevent such corrosion of the element parts, for example. In this method, a protective film covers a surface of element parts formed on one of the substrates, and the bonded substrates are then formed by bonding the pair of substrates together. This protective film prevents corrosion of the surface of the element parts caused by the etching solution entering the substrate during the step of wet-etching.

### RELATED ART DOCUMENT

### Patent Document

Patent Document 1: Japanese Patent Application Laid-Open Publication No. 2010-230782

### SUMMARY OF THE INVENTION

### Problems to be Solved by the Invention

However, merely covering the surface of the element parts with a protective film, as in the method in Patent Document 1, has a risk that the etching solution will enter from the spaces between the substrate and the element parts when the etching solution enters the substrate during the step of wet-etching. Therefore, the element parts are not able to be sufficiently protected, and the reliability of the display device cannot be guaranteed.

The present invention was made taking into account the above-mentioned problems. The present invention aims to provide a method of manufacturing a display device with improved reliability.

### Means for Solving the Problems

The present invention relates to a method of manufacturing display devices, including: forming a protective film on a first base substrate; forming an element part on the first base substrate and/or the protective film; bonding a second base substrate to the first base substrate to form bonded substrates including both substrates, the element part being therebetween; forming, after the step of bonding, a first incision on a surface of the first base substrate opposite to a surface on which the protective film is formed, at a location overlapping with the protective film; wet-etching the formed first incision to make the incision deeper; forming, after the step of etching, a second incision on a surface of the second base substrate opposite to a surface facing the element part, at a location overlapping with the first incision, and dividing the bonded substrates along the first incision and the second incision, thereby forming a plurality of individual bonded substrates.

According to the method of manufacturing display devices described above, even if the first incision is formed deep enough to go through the first base substrate during the step of the first incision and the step of etching, the etching solution is prevented from entering by the protective film formed on the first base substrate, so the etching solution does not reach the element part. Thus, corrosion of the element part due to the etching solution entering the bonded substrates can be prevented in the manufacturing process, and a display device with improved reliability can be manufactured.

The method may further include forming on the element part a sealing part including a sealing agent after the step of forming the element part, and bonding a second base substrate to the sealing part on the first base substrate in the step of bonding.

With this method of manufacturing, the second base substrate can be easily bonded to the first base substrate because of the sealing part.

The sealing part, which has a circular shape, may be formed on the element part in the step of forming the sealing part.

With this method of manufacturing, the etching solution can be prevented from entering into the area surrounded by the circular sealing part in the step of etching.

A plurality of the element parts may be formed on the first base substrate in the step of forming the element part, and the first incision may be formed at a location overlapping with a space between the adjacent sealing parts in the step of the first incision.

With this method of manufacturing, the bonded substrates are divided at the space between the sealing parts into a plurality of individual bonded substrates in the step of individual dividing. Thus, a plurality of individual substrates can be formed, the sides thereof being formed by the sealing parts.

The first incision may be formed at a location overlapping with a space between the adjacent element parts in the step of the first incision.

With this method of manufacturing, the bonded substrates can be individually divided in the step of individual dividing without cutting the element parts.

A terminal part that is capable of connecting an external substrate to one end of the element part may be formed in the step of forming the element part, and the sealing part may be formed such that the terminal part is positioned between the adjacent sealing parts in the step of forming the sealing part.

With this method of manufacturing, a plurality of the individual bonded substrates that are provided with the terminal parts capable of connecting an external substrate can be formed in the step of individual dividing.

The protective film may be formed on the first base substrate and the second base substrate in the step of forming the protective film, and the second base substrate may be bonded to the first base substrate in the step of bonding such that a surface of the second base substrate on which the protective film is formed faces the first base substrate.

With this method of manufacturing, even if the second incision is formed deep enough to go through the second base substrate in the step of the second incision, the protective film formed on the second base substrate can prevent foreign objects entering the bonded substrates from the second incision.

The protective film may be formed on a portion of the first base substrate in the step of forming the protective film.

With this method of manufacturing, in the step of forming the element part, the thickness of the bonded substrates can be reduced because the protective film and the element parts do not overlap, due to forming the element parts on locations of the first base substrate where the protective film is not formed.

The protective film may be formed using a spin coating method or a slit coating method in the step of forming the protective film.

With this method of manufacturing, the protective film is easy to form in the step of forming the protective film.

A polyimide may be used as the protective film in the step of forming the protective film.

With this method of manufacturing, a specific material for preventing the etching solution entering the bonded substrates can be used to form the protective film in the step of forming the protective film.

The protective film may be formed with a thickness of 5 to 200 μm in the step of forming the protective film.

With this method of manufacturing, a specific thickness for preventing the etching solution entering the bonded substrates can be used to form the protective film in the step of forming the protective film, if forming the protective film from a polyimide.

Hydrofluoric acid may be used as the etching solution in the step of etching.

With this method of manufacturing, a specific etching solution for etching the first base substrate can be used in the step of etching.

The present invention may be a method of manufacturing liquid crystal display devices using the method of manufacturing display devices described above. In this case, forming a liquid crystal layer on the element part may be included after the step of forming the element part.

With the method of manufacturing liquid crystal display devices described above, corrosion of the element part in the steps of manufacturing can be prevented, and liquid crystal display devices with improved reliability can be manufactured.

In the method of manufacturing liquid crystal display devices described above, the element part provided with a plurality of thin-film transistors may be formed in the step of forming the element part, and the second base substrate having colored parts and light-shielding parts formed thereon may be bonded in the step of bonding.

With this method of manufacturing, a so-called active matrix substrate provided with the plurality of thin-film transistors can be bonded together with a so-called color filter substrate whereon the color filters are formed, and liquid crystal display devices with a specific configuration can be manufactured.

The present invention may be liquid crystal display devices manufactured by the method of manufacturing liquid crystal display devices described above.

### Effects of the Invention

According to the present invention, a display device with improved reliability can be manufactured.

### BRIEF DESCRIPTION OF THE DRAWINGS

FIG. 1 shows a cross-sectional view of a liquid crystal display device 10 of Embodiment 1.

FIG. 2 shows a cross-sectional view of a part of a liquid crystal panel 11.

FIG. 3 shows a plan view of the liquid crystal panel 11.

FIG. 4 shows an expanded plan view of a terminal part 54a on an element part 54.

FIG. 5 shows an expanded plan view of a part of an active matrix substrate 30.

FIG. 6 shows a flow chart of steps of manufacturing the liquid crystal panel 11.

FIG. 7 shows a step (1) in a method to manufacture the liquid crystal display device 10.

FIG. 8 shows a step (2) in a method to manufacture the liquid crystal display device 10.

FIG. 9 shows a step (3) in method to manufacture the liquid crystal display device 10.

FIG. 10 shows a step (4) in a method to manufacture the liquid crystal display device 10.

FIG. 11 shows a step (5) in a method to manufacture the liquid crystal display device 10.

FIG. 12 shows a step (6) in a method to manufacture the liquid crystal display device 10.

FIG. 13 shows a step (7) in a method to manufacture the liquid crystal display device 10.

FIG. 14 shows a step in a method to manufacture a liquid crystal display device of Embodiment 2.

FIG. 15 shows a step (1) in a method to manufacture a liquid crystal display device of Embodiment 3.

FIG. 16 shows a step (2) in a method to manufacture the liquid crystal display device of Embodiment 3.

### DETAILED DESCRIPTION OF EMBODIMENTS

### Embodiment 1

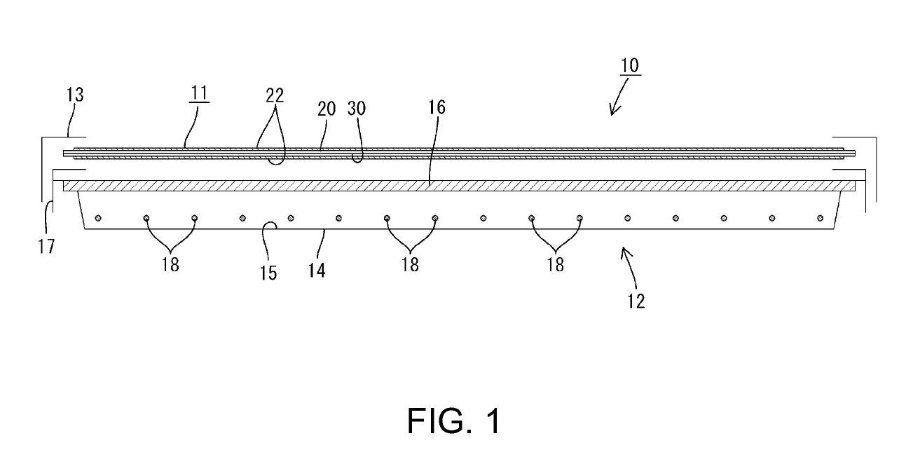

Embodiment 1 will be described with reference to the drawings. FIG. 1 shows a cross-sectional view of a liquid crystal display device 10 according to Embodiment 1. The upper side of FIG. 1 is the front side, and the lower side is the rear side. As shown in FIG. 1, the liquid crystal display device 10 includes a liquid crystal panel 11 that is a display panel, and a backlight device 12 that is an external light source, and these are held together as one component by a frame shaped bezel 13 or the like.

First, a configuration of the backlight device 12 will be briefly explained. The backlight device 12 is a so-called direct-lit backlight device, where a light source is placed directly on the back of the liquid crystal panel 11. The backlight device 12 includes: a chassis 14 that has a light exiting section on the front (light exiting side, liquid crystal panel 11 side) thereof; a reflective sheet 15 provided inside the chassis 14; an optical member 16 attached so as to cover the light exiting section of the chassis 14; a frame 17 for affixing the optical member 16; a plurality of cold cathode fluorescent tubes 18 that are housed parallel to each other in the chassis 14; and a lamp holder 19 that blocks the ends of the cold cathode fluorescent tubes 18 from light and that has light reflective properties.

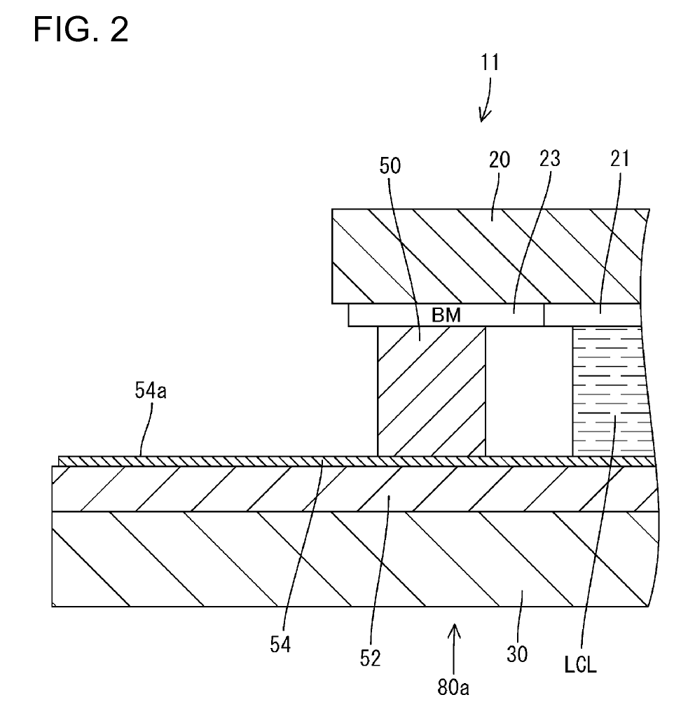

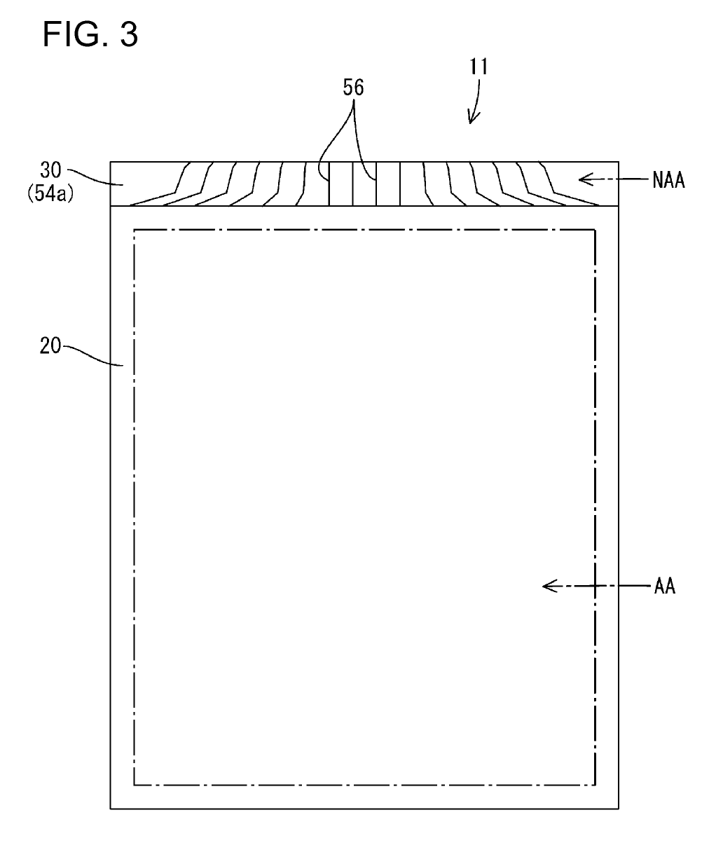

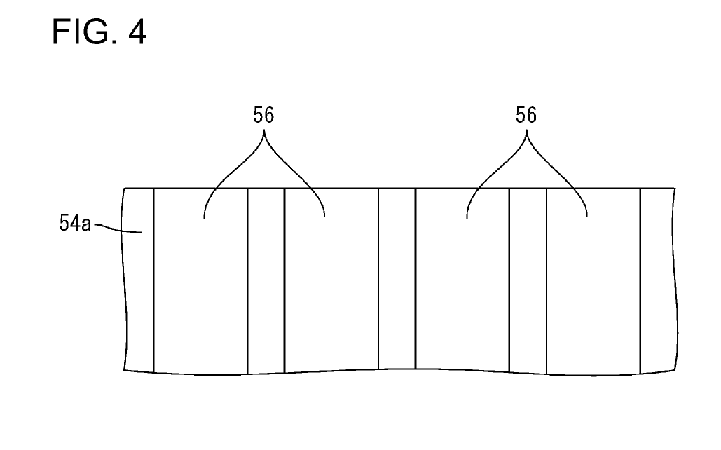

Next, a configuration of the liquid crystal panel 11 will be briefly explained below. FIG. 2 shows a cross-sectional view of a part of the liquid crystal panel 11. FIG. 3 shows a plan view of the liquid crystal panel 11. FIG. 4 shows an expanded plan view of a terminal part 54a on an element part 54. As shown in FIGS. 2 and 3, the liquid crystal panel 11 is made of a liquid crystal layer LCL that includes a liquid crystal material sealed between a pair of rectangular transparent (having transparent properties) glass substrates 20 and 30. The liquid crystal material is a substance that changes optical characteristics according to an applied electric field. Both substrates 20 and 30 are bonded together by a sealing part 50 made of a sealing agent in a state where a gap is maintained that matches the thickness of the liquid crystal layer LCL.

Among the two substrates 20 and 30 that form the liquid crystal panel 11, the substrate placed on the back side (the backlight device 12 side) is the active matrix substrate 30, and the substrate placed on the front side (the light exiting side) is the CF substrate (an example of a color filter substrate) 20. As shown in FIG. 2, the inner surface (the liquid crystal layer LCL side, the side opposite to the CF substrate 20) of the active matrix substrate 30 has a protective film 52 formed thereon, and the element part 54 is formed on the protective film 52. The terminal part 54a is formed at a location above the element part 54 and not overlapping the CF substrate 20. An alignment film (not shown) facing the liquid crystal layer LCL is formed on each inner surface of the substrates 20 and 30 for orienting the liquid crystal molecules that are included in the liquid crystal layer LCL. In the liquid crystal panel 11, the pre-tilt angle of the liquid crystal molecules inside the liquid crystal layer LCL is controlled by irradiating these alignment films with ultraviolet rays.

As shown in FIG. 3, the liquid crystal panel 11 has a display area AA (the portion enclosed by the dashed line in FIG. 3) where images are displayed and a substantially frame-shaped non-display area NAA located on the periphery of the display area AA. Images are not shown on the non-display area NAA. As shown in FIG. 1, a set of front and rear polarizing plates 22 is bonded to the respective outer surfaces of the substrates 20 and 30. The size (area) of both of the substrates 20 and 30 is approximately the same as the display area AA. As shown in FIG. 3, the terminal part 54a on the element part 54 formed on the active matrix substrate 30 has a plurality of terminals 56. As shown in FIG. 4, the terminals 56 are arranged parallel in a straight line with no breaks. A flexible substrate, which is an external substrate, is capable of being connected to these terminals 54 on the terminal part 54a.

Next, a configuration of the CF substrate 20 will be explained. The inner surface (the liquid crystal layer LCL side, opposite from the active matrix substrate 30) in the CF substrate 20 is provided with color filters made of colored parts 21 that include R (red), G (green), and B (blue), respectively. A plurality of the colored parts 21 are arranged in a matrix at a location overlapping in a plan view with each pixel electrode 36 on the active matrix substrate 20, described later. Between each of the colored parts constituting the color filters, a light-shielding part (a black matrix) 23 is formed in a grid pattern in order to prevent color mixing. The light-shielding part 23 is arranged to overlap in a plan view with source wiring lines 38, gate wiring lines 32, and Cs wiring lines 34 on the active matrix substrate 30, described later. The surface of each colored part 21 and the light-shielding part 23 is provided with an opposite electrode 26 that opposes the pixel electrodes 36 on the active matrix substrate 30. The opposite electrode 26 is a transparent film electrode made of an ITO (indium tin oxide) film or the like, for example, and the whole surface thereof is formed in a solid shape.

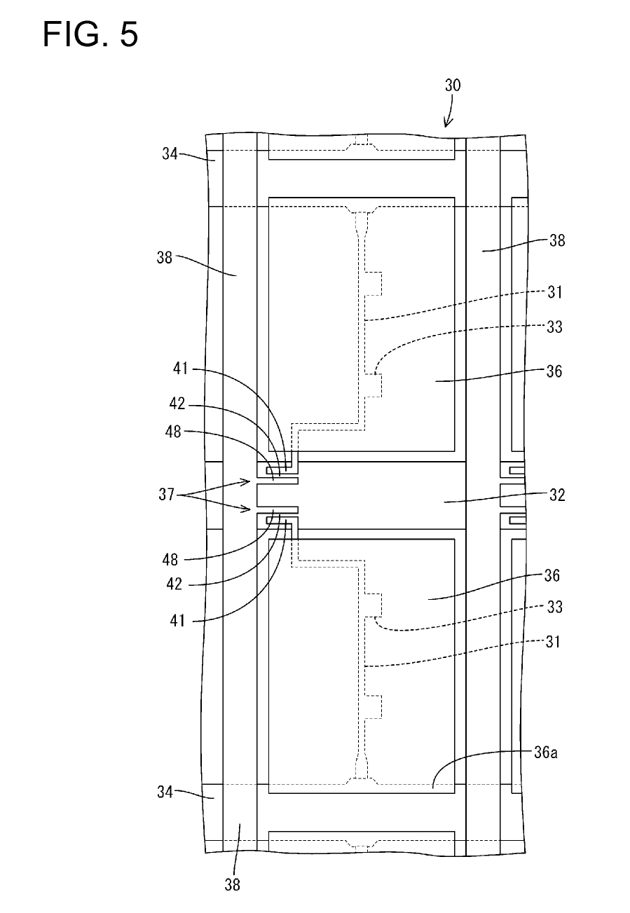

Next, the active matrix substrate 30 will be explained. FIG. 5 shows an expanded plan view of a part of the active matrix substrate 30. As shown in FIG. 5, a plurality of the mutually parallel source wiring lines (signal wiring lines) 38 that extend along the Y-axis direction (the column direction, the vertical direction), a plurality of the mutually parallel gate wiring lines 32 that extend along the X-axis direction (the row direction, the horizontal direction), or in other words, the direction perpendicular to (intersecting) the source wiring lines 38, and a plurality of the mutually parallel Cs wiring lines 34 that are arranged between each gate wiring line 32 and that are in parallel with the gate wiring lines 32 are formed in a grid shape on the element part 54 on the inner surface (the liquid crystal layer LCL side, the side opposite to the CF substrate 20) of the active matrix substrate 30. Hereinafter, the vertical direction in FIG. 5 is called the column direction, and the horizontal direction in FIG. 5 is called the row direction.

The gate wiring lines 32 and the Cs wiring lines 34 are alternately arranged, and configured such that the distance between the adjacent gate wiring lines 32 and Cs wiring lines 34 is substantially equal. The source wiring lines 38 extend in the column direction along an end (the end along the direction perpendicular to the gate wiring lines 32) of each pixel area PE, and the source wiring lines 38 are formed with a comparatively small width in comparison to the gate wiring lines 32 and the Cs wiring lines 34. The Cs wiring lines 34 extend in the row direction such that a portion of the Cs wiring lines 34 overlaps each end of two pixel areas, which are each adjacent in the column direction. The gate wiring lines 32 and the Cs wiring lines 34 are arranged in a layer that is relatively lower than the source wiring lines 38. A gate insulating film (not shown) is present between the mutually intersecting source wiring lines 38, and gate wiring lines 32 and the Cs wiring lines 38, resulting in these being insulated from each other. In a layer further above the source wiring lines 38, which are arranged in a relatively upper layer, a not-shown interlayer insulating film (passivation film, protective layer) is provided, and this interlayer insulating film protects the source wiring lines 38.

As shown in FIG. 5, a TFT 37 is formed at an intersection of each source wiring line 38 and each gate wiring line 32 as a switching element that connects to both wiring lines 38 and 32. The TFT 37 is a so-called inversed staggered type (bottom gate type), and is placed on the gate wiring line 32. A portion of the gate wiring line 32 acts as a gate electrode 42. A scanning signal inputted to the gate wiring line 32 is supplied at prescribed times to this gate electrode 42. The branch line continuing to the TFT 37 from the source wiring line 38 forms a source electrode 48 of the TFT 37 that overlaps the gate electrode 42 via a semiconductor film and the like (not shown). An image signal (data signal) inputted to the source wiring line 38 is supplied to this source electrode 48.

As shown in FIG. 5, a plurality of vertically-long quadrilateral pixel electrodes 36 are arranged in a matrix in areas surrounded by the source wiring lines 38, gate wiring lines 32, and Cs wiring lines 34. A drain wiring line 42 is connected to the pixel electrode 36 via a contact hole 44, and an end of this drain wiring line 42 continues to the TFT 37 to act as a drain electrode 41 that overlaps the gate electrode 42 via the semiconductor film and the like (not shown). This drain wiring line 42 is made of the same material, in the same step, and in the same layer as the source wiring line 38, and is provided in a layer above the gate wiring line 32 and the Cs wiring line 34. The end of the pixel electrode 36 near the Cs wiring line 34 is placed so as to overlap the Cs wiring line 34 via a gate insulating film 48 and the interlayer insulating film, thereby forming a capacitance between the Cs wiring line 34 and the pixel electrode 36 (see reference character 36a). This allows the voltage of the pixel electrode 36 to be maintained even when a scanning signal is not being inputted (when the TFT is OFF) to the gate electrode 42 of the TFT 37. The pixel electrode 36 is made of a transparent film electrode such as ITO or ZnO (zinc oxide). The active matrix substrate 30 of the present embodiment adopts the so-called multi-pixel driving scheme in which one pixel area, which corresponds to one display unit, is divided into two sub-pixels and driven. This results in favorable viewing angle characteristics.

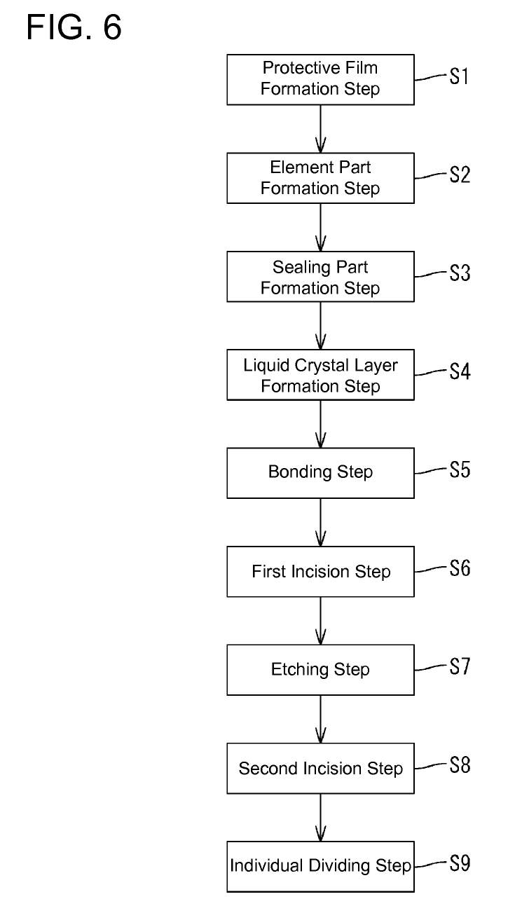

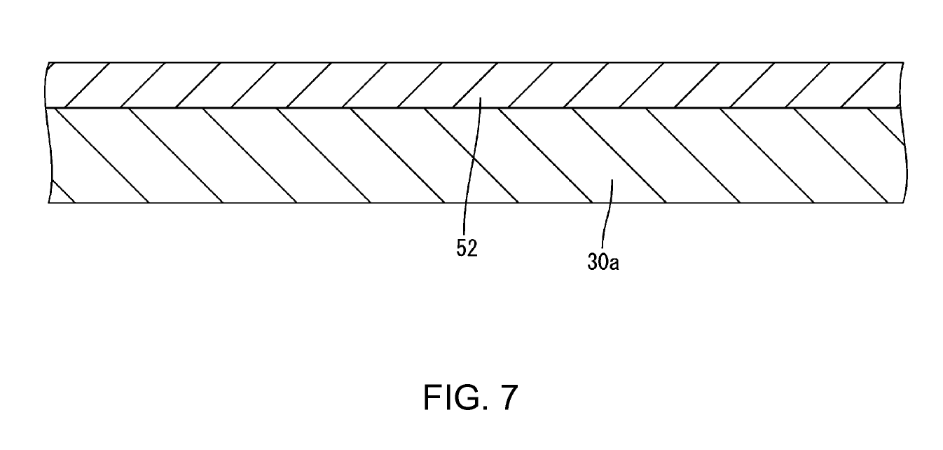

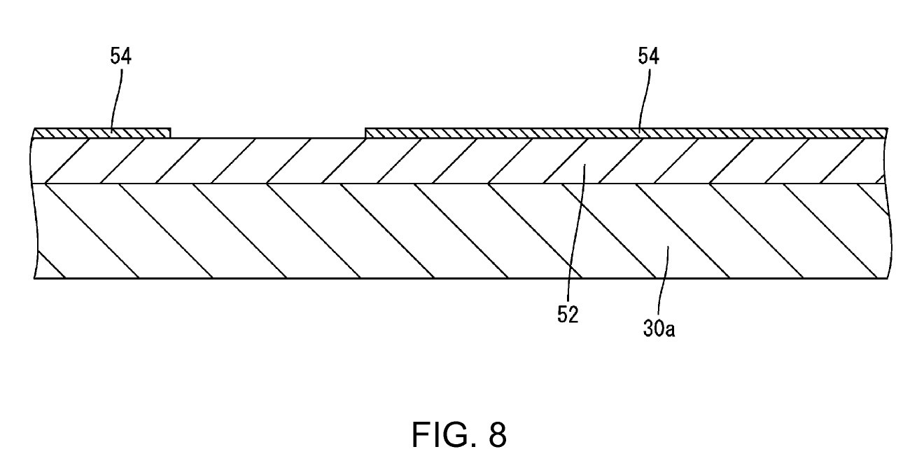

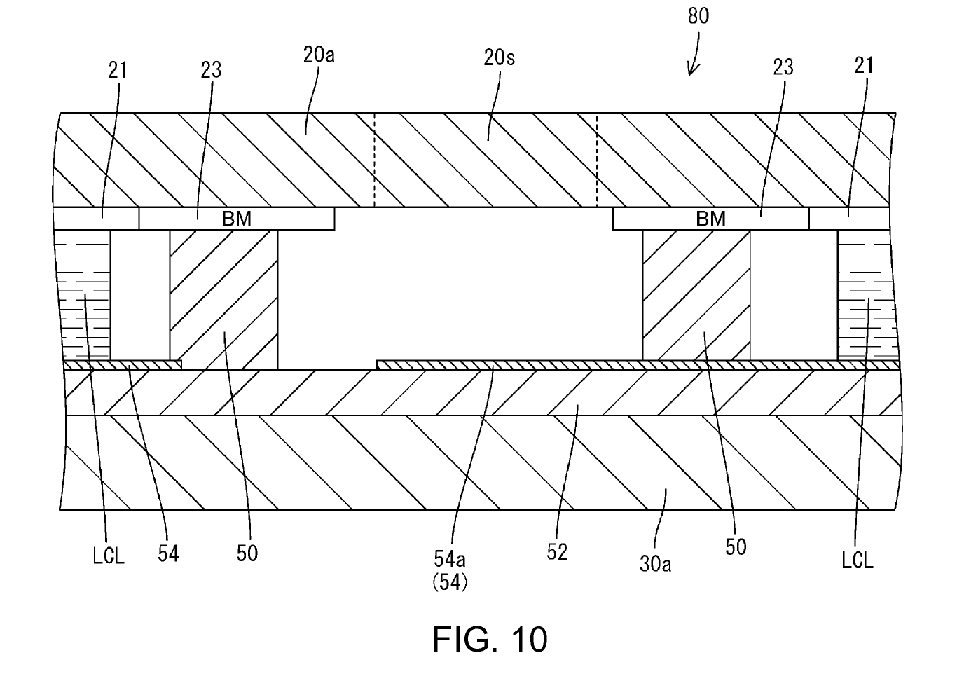

Next, a method to manufacture the liquid crystal display device 10 provided with the liquid crystal panel 11 described above will be explained. FIG. 6 shows a flowchart of steps to manufacture the liquid crystal panel 11, taken from the manufacturing process of the liquid crystal display device 10. The liquid crystal display device 10 can be manufactured by attaching the backlight device 12 (the method of manufacturing thereof being omitted in the present embodiment) to the liquid crystal panel 11. FIGS. 7 to 13 show steps (1) to (7) in the method to manufacture the liquid crystal display device 10.

In the present method, first a rectangular first base substrate 30a is prepared as a glass substrate that will act as the active matrix substrate 30 described above in the manufactured liquid crystal panel 11. As shown in FIG. 1, the protective film 52 made of a polyimide is formed on the first base substrate 30a (one example of forming a protective film, corresponding to S1 in FIG. 6). This protective film 52 is formed using a spin coating method or slit coating method on the first base substrate 30a, and the thickness of the protective film 52 is in the range of 5 to 200 μm.

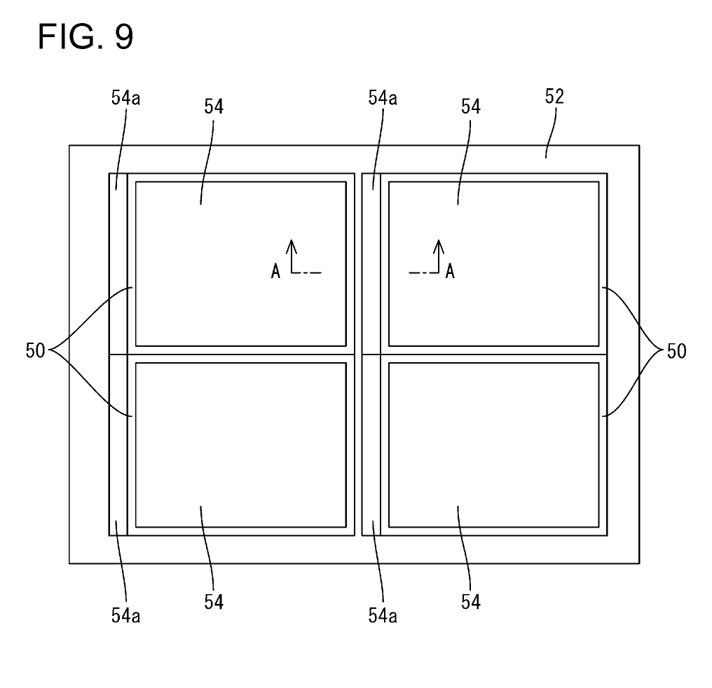

Next, the element parts 54 provided with transistors and circuit wiring that form the active matrix circuits such as the TFTs 37, gate wiring lines 42, and Cs wiring lines 38 described above are formed on a portion of the protective film 52 (an example forming element parts, corresponding to S2 in FIG. 6). In the present embodiment, a method is illustrated in which four liquid crystal panels 11 are manufactured from one set of bonded substrates 80. Therefore, in the step of forming the element parts, four element parts 54 are respectively formed on a portion of the protective film 52 (see FIG. 9). As shown in FIG. 9, each element part 54 is formed such that the terminal part 54a formed on each element part 54 aligns on one side (the left side in the example shown in FIG. 9).

Next, the sealing agent is applied on each of the four element parts 54 formed on the protective film 52 in order to form four sealing parts 50 (an example of forming sealing parts, corresponding to S3 in FIG. 6). Specifically, as shown in FIG. 9, each substantially square frame-shaped sealing member 50 is formed in a plan view. At this time, each sealing part 50 is formed such that the terminal part 54a on the element part 52 is positioned outside the area surrounded by the sealing part 50. An ultraviolet curable resin or the like can be used as the sealing agent. After the step of forming the sealing parts, liquid crystal is dripped on the element part 52 in each area surrounded by the sealing part 50 in order to form the liquid crystal layer LCL in each area (an example of forming a liquid crystal layer, corresponding to S4 in FIG. 6).

A rectangular second base substrate 20a with approximately the same size as the first base substrate 30a is prepared as a glass substrate that will act as the CF substrate 20 described above in the manufactured display panel 11. The colored parts 21 and light-shielding parts 23 described above are formed on the second base substrate 20a. At this time, the colored parts 21 and light-shielding parts 23 are formed at locations that respectively overlap the four areas surrounded by the sealing parts 50 when the first base substrate 30a and the second base substrate 20a are bonded together. After the step of forming the liquid crystal layer, the second base substrate 20a whereupon the color filters CF are formed is bonded together across the element parts 52 with the first base substrate 30a, which is where the sealing parts 50 and the liquid crystal layer LCL are formed (an example of bonding, corresponding to S5 in FIG. 6). Accordingly, the liquid crystal layer LCL, the colored parts 21, and the light-shielding parts 23 are positioned in the inner surface of the bonded substrates 80 in a state surrounded by the circular sealing parts 50. In other words, the liquid crystal layer LCL, the colored parts 21, and the light-shielding parts 23 are enclosed by the sealing parts 50 and both substrates 30a and 20a.

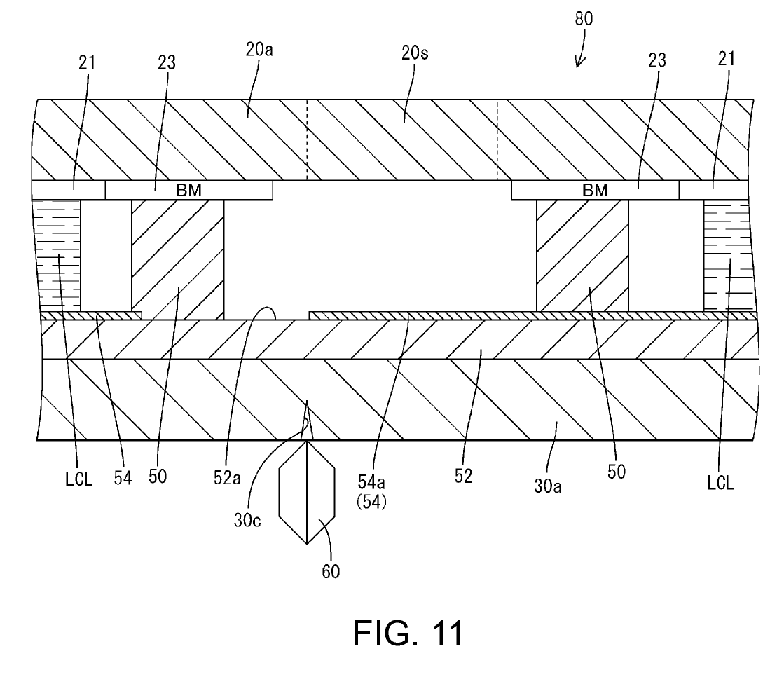

Next, as shown in FIG. 11, a scribe scheme using a cutting wheel 60 forms a first scribe line (an example of a first incision) 30c on a surface of the outside (the side opposite to where the element parts 54 are formed) of the first base substrate 30a in the bonded substrates 80 (an example of a first incision, corresponding to S6 in FIG. 6). At this time, the first scribe line 30c that divides the first base substrate 30a in four is formed such that the four sealing parts 50 are each divided along a section (a section where no element parts 54 are formed) 52a that is between the adjacent sealing parts 50 and that overlaps the spaces between the adjacent element parts 54 on the protective film 52. In FIG. 11, a portion 20s of the second base substrate 20a where both sides thereof are demarcated by dotted lines is overlapping the terminal part 54a formed on the first base substrate 30a, and one of the dotted lines overlaps the first scribe line 30c. The portion 20s demarcated by these dotted lines is an unnecessary portion 20s, which is unnecessary when the bonded substrates 80 are divided into individual substrates.

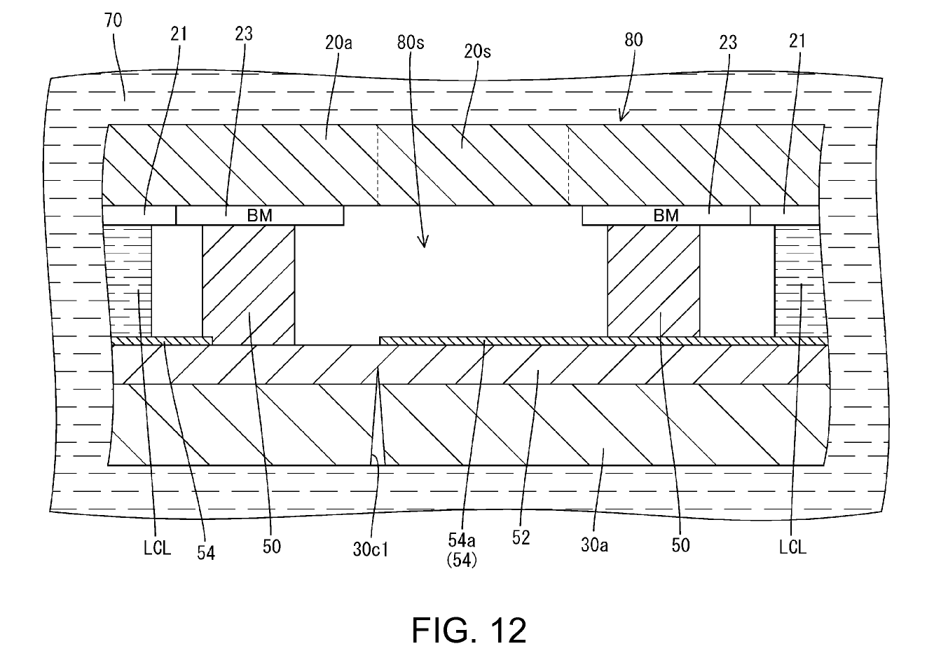

Next, as shown in FIG. 12, the bonded substrates 80 are immersed into an etching solution 70 in order to wet-etch the first scribe line 30c (an example of etching, corresponding to S7 in FIG. 6). This grows the first scribe line 30c and makes a scribe line 30c1 even deeper. Hydrofluoric acid can be used as the etching solution 70 used for wet-etching. As shown in FIG. 12, even if wet-etching deepens the first scribe line 30c enough to go through the first base substrate 30a, the first base substrate 30a has the protective film 52 formed thereon, so the protective film 52 prevents the etching solution 70 from entering into an inner side 80s of the bonded substrates 80.

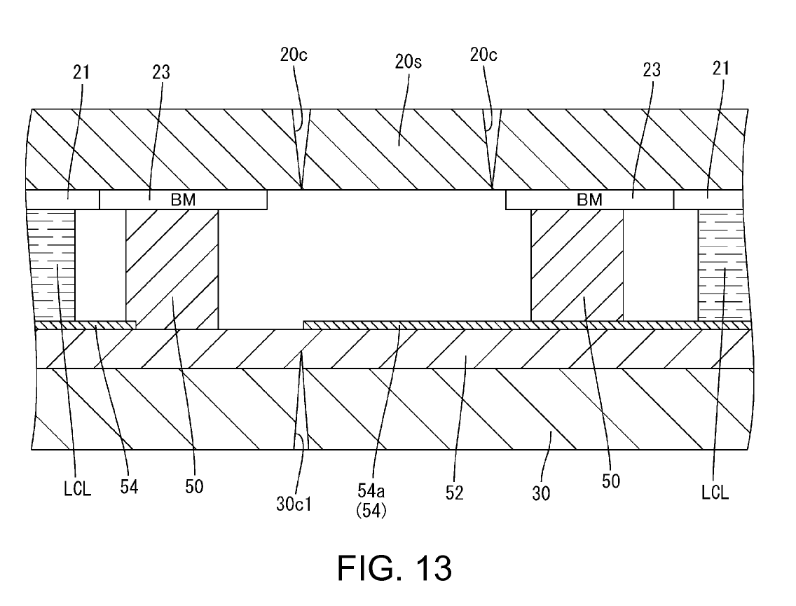

Next, as shown in FIG. 13, on the surface on the outside (a side opposite to the side facing the element parts 54) of the second base substrate 20a, a scribe scheme using a cutting wheel forms second scribe lines (one example of a second incision) 20c along the dotted lines (see FIGS. 11 and 12) on both sides of the unnecessary portion 20s (an example of a second incision, corresponding to S8 in FIG. 6).

Next, the bonded substrates 80 are divided along the first scribe line 30c and the second scribe lines 20c (an example of individual dividing, corresponding to S9 in FIG. 6). This divides the bonded substrates 80 into four individual bonded substrates 80a (see FIG. 2), and removes the unnecessary portion 20s of the second base substrate 20a. The protective film 52 is formed so as to overlap the first scribe line 30c, but at this time the protective film 52 can be easily separated by separating the four individual bonded substrates 80a that have been divided into four. As shown in FIG. 2, in the individual bonded substrates 80a formed as such, a substrate that was a part of the first base substrate 30a before the step of individual dividing acts as the active matrix substrate 30, and a substrate that was a part of the second base substrate 20a before the step of individual dividing acts as the CF substrate 20. In other words, the individual bonded substrates 80a have the same configuration as the liquid crystal panel 11.

Next, the liquid crystal display device 10 shown in FIG. 1 can be manufactured by attaching the backlight device 12 to each set of individual bonded substrates 80a divided in the step of individual dividing, or in other words, to each liquid crystal panel 11. As such, in the method of manufacturing of the present embodiment, as described above, the etching solution 70 is prevented from entering into the inner side 80s of the bonded substrates 80 in the step of etching, and thus the terminal part 54a is not in contact with the etching solution 70. As shown in FIG. 4, it is possible to make it so that disconnection and corrosion do not occur on the terminal part 54a.

In the method of manufacturing a liquid crystal display device 10 of the present embodiment as described above, even if the first scribe line 30c is formed deep enough to go through the first base substrate 30a in the step of the first incision and the step of etching, the protective film 52 formed on the first base substrate 30a prevents the etching solution 70 from entering, so the etching solution 70 does not reach the terminal part 54a formed in the element part 54. Thus, corrosion of the terminal part 54a due to the etching solution 70 entering the inner side 80s can be prevented in the manufacturing process, and a liquid crystal display device 10 with improved reliability can be manufactured.

In conventional methods of manufacturing that cover the surface of the terminal part with a protective film, the protective film needs to be removed after the step of individual dividing in order to ensure the functionality of the terminal part. However, the material that can be used to remove the protective film is limited, resulting in difficulty relating to removal of the protective film after the step of individual dividing. As a countermeasure, in the method of manufacturing the liquid crystal display device 10 of the present embodiment, the surface of the terminal part 54a is not covered with the protective film 52, so the functionality of the terminal part 54a can be ensured even if the protective film 52 is not removed after the step of individual dividing.

In the method of manufacturing the liquid crystal display device 10 of the present embodiment, a step of forming the sealing parts 50 on the element parts 54 is further provided after the step of forming the element parts. In the step of bonding, the second base substrate 20a is bonded to the sealing parts 50 on the first base substrate 30a. This results in the second base substrate 20a being easy to bond to the first base substrate 30a due to the sealing parts 50.

In the method of manufacturing the liquid crystal display device 10 of the present embodiment, the circular sealing parts 50 are formed on the element parts 54 in the step of forming the sealing parts. Therefore, etching solution 70 entering into the areas surrounded by the circular sealing parts 50 can be prevented in the step of etching.

In the method of manufacturing the liquid crystal display device 10 of the present embodiment, the four element parts 54 are formed on the first base substrate 30a in the step of forming the element parts, and the first scribe line 30c is formed at a location overlapping the spaces between the adjacent sealing parts 50 in the step of the first incision. Thus, the bonded substrates 80 are divided into a plurality of individual substrates between the adjacent sealing parts 50 in the step of individual dividing, and a plurality of individual bonded substrates 80a can be formed, the sides thereof being formed by the sealing parts 50.

In the method of manufacturing the liquid crystal display device 10 of the present embodiment, the first scribe line 54c is formed at a location overlapping spaces between the adjacent element parts 54 in the step of the first incision. Therefore, the bonded substrates 80 can be individually divided in the step of individual dividing without cutting the element parts 54.

In the method of manufacturing the liquid crystal display device 10 of the present embodiment, the terminal parts 54a that are capable of connecting a flexible substrate, which is an external substrate, to one end of the element parts 54 are formed in the step of forming the element parts, and the sealing parts 50 are formed in the step of forming the sealing parts such that the terminal parts 54a are positioned between the adjacent sealing parts 50. Thus, a plurality of the individual bonded substrates 80a that are provided with the terminal parts 54a capable of connecting an external substrate can be formed in the step of individual dividing.

In the method of manufacturing the liquid crystal display device 10 of the present embodiment, the protective film 52 is formed on the first base substrate 30a and second base substrate 20a in the step of forming the protective film, and the second base substrate 20a is bonded to the first base substrate 30a with the surface of the second base substrate 20a where the protective film 52 is formed facing the first base substrate 30a. As a result, foreign objects can be prevented from entering the second scribe lines 20c by the protective film 52 formed on the second base substrate 20a even if the second scribe lines 20c are formed deep enough to go through the second base substrate 20a.

### Embodiment 2

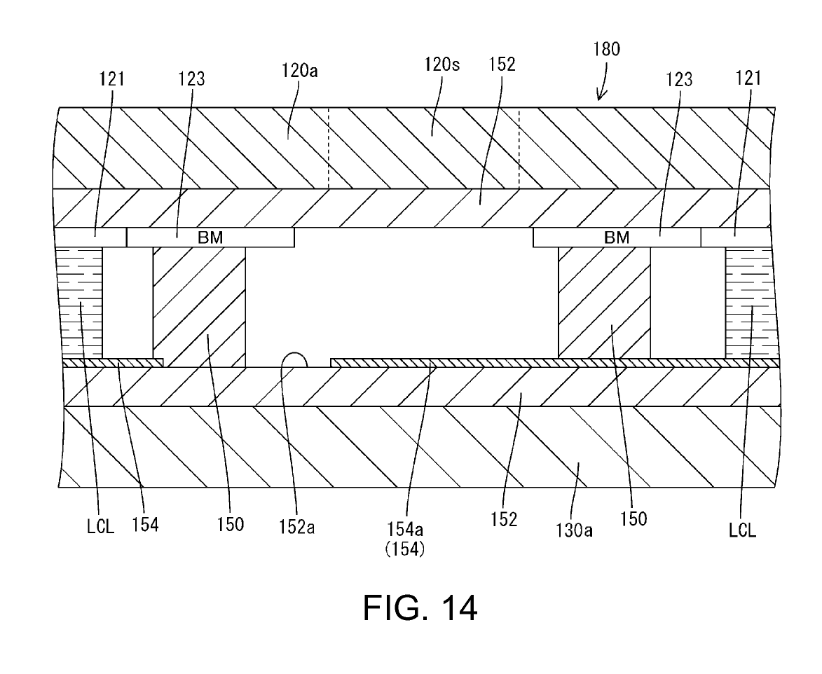

Embodiment 2 will be described with reference to the drawings. FIG. 14 shows a step in a method of manufacturing a liquid crystal display device 110 according to Embodiment 2. In Embodiment 2, the extent to which a protective film 152 is formed in a step of forming a protective film differs from Embodiment 1. Other steps in the method of manufacturing and configurations of the manufactured liquid crystal display device 110 are the same as in Embodiment 1, and thus an explanation of the other steps in the method of manufacturing, structures, effects, and results will be omitted. In FIG. 14, parts where 100 has been added to reference character from FIG. 11 are the same parts described in Embodiment 1.

The method of manufacturing the liquid crystal display device 110 of Embodiment 2, as shown in FIG. 14, has the protective film 152 formed on both a first base substrate 130a and a second base substrate 130a in the step of forming the protective film. Colored parts 121 and light-shielding parts 123 are formed on the protective film 152 of the second base substrate 120a, and the second base substrate 120a is bonded to the first base substrate 130a, which has element parts 154 formed thereon. By also forming the protective film 152 on the second base substrate 120a in this way, foreign objects or the like can be prevented from entering bonded substrates 180 from second scribe lines even if the second scribe lines are formed deep enough to go through the second base substrate 120a in a step of a second incision, for example.

### Embodiment 3

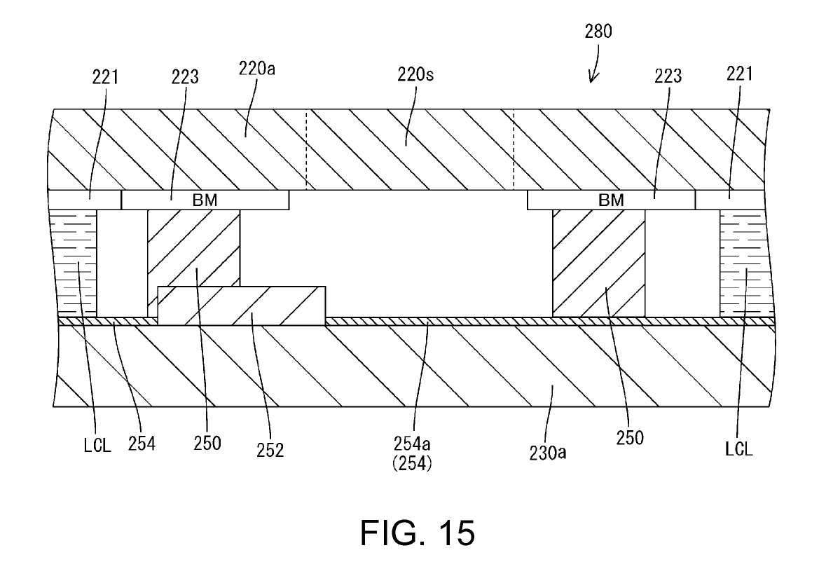

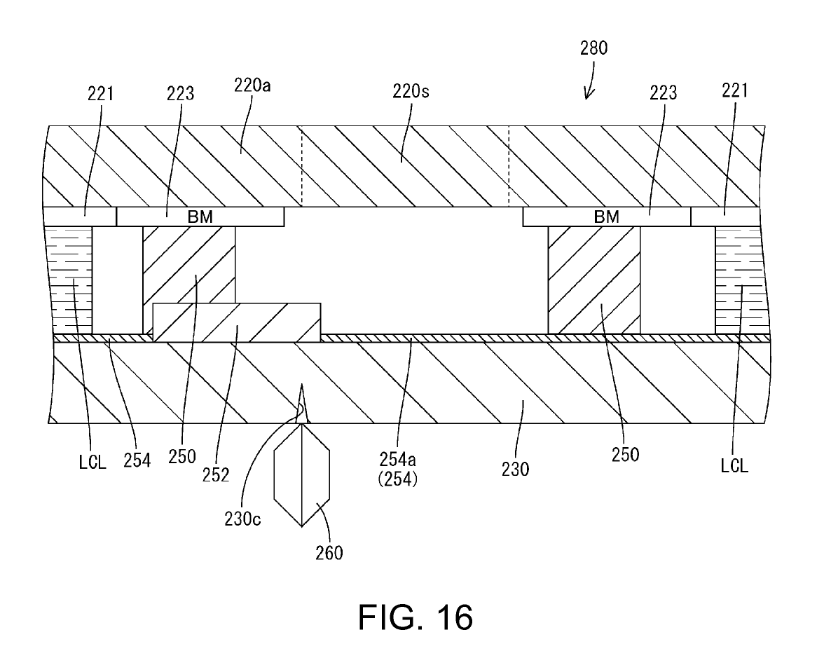

Embodiment 3 will be described with reference to the drawings. FIGS. 15 and 16 show steps (1) and (2) in a method to manufacture a liquid crystal display device according to Embodiment 3. In Embodiment 3, the extent to which a protective film 252 is formed in a step of forming a protective film, and the extent to which element parts 254 are formed in a step of forming element parts, differ from Embodiment 1. Other steps in the method of manufacturing and configurations of a manufactured liquid crystal display device 210 are the same as in Embodiment 1, and thus an explanation of the other steps in the method of manufacturing, structures, effects, and results will be omitted. In FIG. 15, parts where 200 has been added to reference characters from FIG. 11, and, in FIG. 16, parts where 200 has been added to reference characters from FIG. 12 are the same parts described in Embodiment 1.

In the method of manufacturing the liquid crystal display device 210 of Embodiment 3, the protective film 252 is formed on only a portion of a first base substrate 230a. Specifically, the protective film 252 is only formed on a portion of the first base substrate 230a, which includes a location overlapping an area where a first scribe line 230c is formed in a step of a first incision. As shown in FIG. 15, in the step of forming the element parts, the element part 254 is formed on the entire surface of a location of the first base substrate 230a that does not have the protective film 252 formed thereon. As shown in FIG. 16, in the step of the first incision, the first scribe line 230c is formed on the outside of the first base substrate 230a at a location overlapping the protective film 252. By forming the protective film 252 only on a portion of the first base substrate 230a in this way, the amount of polyimide consumed, which is the material of the protective film 252, can be suppressed. The element part 254 is not formed on the protective film 252 but rather on the first base substrate 230a, so bonded substrates 280 can be made thinner by an amount equal to the thickness of the protective film 252 compared with the method of manufacturing in Embodiments 1 and 2, and the liquid crystal display device can be made smaller.

Modification examples of the respective embodiments above will be described below.

(1) In each embodiment described above, a method of manufacturing is illustrated in which the bonded substrates are divided in four to form four individual bonded substrates, but the dividing aspect of the bonded substrates is not limited to this.

(2) In each embodiment described above, a method is illustrated in which the scribe line is formed on the bonded substrates using a scribe scheme, but the method to form the dividing line for dividing the bonded substrates is not limited to this.

(3) In each embodiment described above, a method of manufacturing is illustrated in which the first base substrate is the active matrix substrate, and the second base substrate is the CF substrate, but the first base substrate may be manufactured as the CF substrate, and the second base substrate may be manufactured as the active matrix substrate. In this case, a protective film may be formed on only the first base substrate set as the CF substrate.

(4) In addition to each embodiment described above, modifications can be made as appropriate to the method to form the protective film, the material of the protective film, the location where the protective film is formed, and the like.

(5) In addition to each embodiment described above, modifications can be made as appropriate to the configuration of the display device.

(6) In each embodiment described above, a liquid crystal display device using a liquid crystal panel as a display panel was illustrated, but the present invention is applicable to a display device that uses another type of display panel. In this case, the configuration of the display device can be modified as appropriate.

Embodiments of the present invention were described above in detail, but these are merely examples, and do not limit the scope defined by the claims. The technical scope defined by the claims includes various modifications of the specific examples described above.

Also, the technical elements described in the present specification or shown in the drawings realize technical utility each on their own or through a combination of various technical elements, and are not limited to the combinations defined by the claims at the time of filing. Also, the techniques described in the present specification or shown in the drawings can accomplish a plurality of objects simultaneously, and each one of the objects on its own has technical utility.

### DESCRIPTION OF REFERENCE CHARACTERS

10 liquid crystal display device
11 liquid crystal panel
12 backlight device
20a, 120a, 220a second base substrate
20c second scribe line
30a, 130a, 230a first base substrate
30c, 230c first scribe line
50, 150, 250 sealing part
52, 152, 252 protective film
54, 154, 254 element part
70 etching solution
80, 180, 280 bonded substrates
AA display area
NAA non-display area

1. A method of manufacturing display devices, comprising:
forming a protective film on a first base substrate;
forming a circuit element part on the first base substrate and/or the protective film;
bonding a second base substrate to the first base substrate to form bonded substrates comprising both substrates, the circuit element part being therebetween;
forming, after the step of bonding, a first incision on a surface of the first base substrate opposite to a surface of the first base substrate on which the protective film is formed, at a location overlapping with the protective film;
wet-etching the formed first incision to make the incision deeper;
forming, after the step of etching, a second incision on a surface of the second base substrate opposite to a surface of the second base substrate facing the circuit element part, at a location overlapping with the first incision, and
dividing the bonded substrates along the first incision and the second incision, thereby forming a plurality of individual bonded substrates.

2. The method of manufacturing display devices according to claim 1, further comprising: forming on the circuit element part a sealing part including a sealing agent after the step of forming the circuit element part,
wherein the second base substrate is bonded to the sealing part on the first base substrate in the step of bonding.

3. The method of manufacturing display devices according to claim 2, wherein the sealing part that has a circular shape is formed on the circuit element part in the step of forming the sealing part.

4. The method of manufacturing display devices according to claim 3,
wherein a plurality of the circuit element parts are formed on the first base substrate in the step of forming the circuit element part, and
wherein the first incision is formed at a location overlapping with a space between the adjacent sealing parts in the step of the first incision.

5. The method of manufacturing display devices according to claim 4, wherein the first incision is formed at a location overlapping with a space between the adjacent circuit element parts in the step of the first incision.

6. The method of manufacturing display devices according to claim 4,
wherein a terminal part that is capable of connecting an external substrate to one end of the circuit element part is formed in the step of forming the circuit element part, and
wherein the sealing part is formed such that the terminal part is positioned between the adjacent sealing parts in the step of forming the sealing part.

7. The method of manufacturing display devices according to claim 1,
wherein the protective film is formed on the first base substrate and the second base substrate in the step of forming the protective film, and
wherein the second base substrate is bonded to the first base substrate in the step of bonding such that a surface of the second base substrate on which the protective film is formed faces the first base substrate.

8. The method of manufacturing display devices according to claim 1, wherein the protective film is formed on a portion of the first base substrate in the step of forming the protective film.

9. The method of manufacturing display devices according to claim 1, wherein the protective film is formed using a spin coating method or a slit coating method in the step of forming the protective film.

10. The method of manufacturing display devices according to claim 1, wherein a polyimide is used as the protective film in the step of forming the protective film.

11. The method of manufacturing display devices according to claim 10, wherein the protective film is formed with a thickness of 5 to 200 μm in the step of forming the protective film.

12. The method of manufacturing display devices according to claim 1, wherein hydrofluoric acid is used as an etching solution in the step of etching.

13. A method of manufacturing liquid crystal display devices using the method of manufacturing display devices according to claim 1, further comprising forming a liquid crystal layer on the circuit element part after the step of forming the circuit element part.

14. The method of manufacturing liquid crystal display devices according to claim 13,
wherein the circuit element part that is provided with a plurality of thin-film transistors is formed in the step of forming the circuit element part, and
wherein the second base substrate that has colored parts and light-shielding parts formed thereon, is bonded in the step of bonding.

15. (canceled)
